(19) United States
(12) Patent Application Publication
(10) Pub. No.: US 2002/0110970 A1
(43) Pub. Date: Aug. 15, 2002

(54) Method of fabricating trench capacitor of a memory cell

(75) Inventor: Li-Wu Tsao, Keelung (TW)

Correspondence Address: Richard P. Berg, Esq., c/o LADAS & PARRY, Suite 2100, 5670 Wilshire Boulevard, Los Angeles, CA, 90036-5679, US

(73) Assignee: NANYA TECHNOLOGY CORPORATION

(21) Appl. No.: 09/916,827

(22) Filed: Jul. 26, 2001

(30) Foreign Application Priority Data
Feb. 9, 2001 (TW) 90102990

(51) Int. Cl. H01L 21/8238

(52) U.S. Cl. 438/200

(57) ABSTRACT

A method of fabricating a trench capacitor of a memory cell is disclosed. A pad layer is formed on the substrate, then, a deep trench is formed. A first insulating layer and a second insulating layer are formed in the deep trench. A photoresist layer fills the deep trench. The portion of the photoresist layer, which is in the upper portion of the deep trench, is removed. After removing the portion of the second insulating layer and the first insulating layer above the residual photoresist layer, the residual photoresist layer is then removed. A collar oxide layer is formed on the surface of the upper portion of the deep trench. The residual first insulating layer and the residual second insulating layer are removed. A seeding layer is formed on the lower portion of the deep trench. A hemispherical silicon grain layer is formed on the seeding layer. The predetermined ions implant into the hemispherical silicon grain layer. By driving the predetermined ions of the hemispherical silicon grain layer into the substrate, a bottom electrode is formed. A capacitor dielectric layer and a top electrode are formed in sequence to complete the fabrication of the trench capacitor of a memory cell.

### BACKGROUND OF THE INVENTION

1. Field of the Invention

The present invention relates to a method of fabricating a capacitor for a dynamic random access memory (DRAM) cell, and more particularly to the fabrication of a trench capacitor for DRAM cell.

2. Description of the Prior Art

A DRAM cell comprises a metal-oxide-semiconductor field effect transistor (MOSFET) and a capacitor that are built in a semiconductor silicon substrate. There is an electrical contact between the drain of a MOSFET and the bottom storage electrodes of the adjacent capacitor, forming a memory cell of the DRAM device. A large number of memory cells make up the cell arrays, which combine with the peripheral circuit to produce DRAMs.

In recent years, the dimensions of the MOSFETs have continuously shrunk so that the packing densities of these DRAM devices have increased considerably; thus, the dimensions of the MOSFETs and capacitors have become smaller. A capacitor is basically composed of an insulating material disposed between two conducting layers. The ability of a capacitor to store charge is related to three physical characteristics: (1) the width of the insulating material; (2) the surface area of the plates; and (3) the electric and/or mechanical characteristics of the insulating material and the plates. However, as the dimensions of the capacitors have become smaller, with commensurate reductions in the capacitance values of the capacitors, there is a reduction in the signal-to-noise ratio of the DRAM circuits, causing performance problems. The issue of maintaining or even increasing the surface area of the bottom storage electrodes or reducing the thickness of the dielectric layer has become particularly important as the density of the DRAM arrays continues to increase for future generations of memory devices. Using a DRAM as an example, in order to better integrate memory, a large number of memory cells must fit into a memory circuit; thus, the base area of a memory cell must be minimized. Also, the plates of a memory cell must have sufficient surface area to store sufficient charge. According to the previously-mentioned characteristics of a capacitor, there are two ways to deal with this problem: increasing the thickness of the bottom storage electrodes or increasing the surface area of the capacitors. Since increasing the thickness of the bottom storage electrodes is very difficult in terms of precision photolithography and etching control, increasing the capacitor surface area is an easier approach when the capacitor is used to fabricate 128 Mbit and higher DRAMs. One of the methods of increasing the integration of a DRAM cell is to form a very deep trench capacitor, instead of the more commonly used stack capacitor. In order to increase the capacitance value of a deep trench capacitor, the surface area of the bottom electrode has to be enlarged. The most efficient way to increase the surface area is to fabricate a hemispherical silicon grains (HSG) layer on the surface of the bottom electrode.

Referring to FIG. 1A, a semiconductor substrate 100 is provided. A pad oxide layer 102, which has a thickness of 40 to 100 angstroms, is formed on the substrate 100 by oxidation. Then, a pad nitride layer 106, which has a thickness of 1000 to 2000 angstroms, is formed by Low Pressure Chemical Vaporization Deposition (referred to as LPCVD hereafter) on the pad oxide 102. The pad oxide 102 and the pad nitride 104 constitute the pad layer 107. Then, a first masking layer 108, which has a thickness of 5000 to 15000 angstroms, is formed on the pad layer 107. The first masking layer 108 is made of BSG, which is made of in-situ doped boron ions formed by Chemical Vaporization (referred to as CVD hereafter).

Referring to FIG. 1B, the first masking layer 108, the pad layer 107 and the substrate 100 are defined to form a deep trench 112 by photolithography and anisotropic etching. The deep trench has a depth of about 6 micron meters. Then, using the pad layer 107 as the mask, the first masking layer 108 is removed by isotropic etching.

Referring to FIG. 1C, a first insulating layer 114 is formed on the inner surface of the deep trench 212, which is the exposed substrate 100. The first insulating layer 114 is made of oxide formed by oxidation. Next, a second insulating layer 116, which has a thickness of ______ angstroms, is formed on the pad layer 107 and extends into the deep trench 112 to cover the sidewalls and the bottom of the deep trench 112. The second insulating layer 116 is made of silicon nitride formed by CVD. A photoresist layer (not shown) fills the deep trench 112 up. Then, the photoresist layer at the upper portion of the deep trench 112 is removed until the distance between the top surface of the remaining photoresist layer and the surface of the substrate 100 is 1500 to 20000 angstroms. The remaining photoresist layer is identified as photoresist layer 118 hereafter.

Referring to FIG. 1D, the portions of the second insulating layer 116 and the first insulating layer 114 above the photoresist layer 118, which is in the deep trench 112, are removed by an anisotropic etching. The remaining first insulating layer 114 and the remaining second insulating layer 116 are referred to as the residual first insulating layer 114′ and the residual second insulating layer 116′ hereafter.

Referring to FIG. 1E, a collar oxide layer 120, which has a thickness of 200 to 500 angstroms, is formed on the surface of the upper portion of the deep trench 112, which is above the top surface of the residual first insulating layer 114′ and the residual second insulating layer 116′. The photoresist layer 118 is then removed.

Referring to FIG. 1F, the residual first insulating layer 114′ and the residual second insulating layer 116′ are removed by anisotropic etching.

Referring to FIG. 1G, a seeding layer 121, which has a thickness of 100 to 200 angstroms, is formed on the pad layer 107 and extends into the deep trench 112 to cover the surface of the collar oxide layer 120 and the sidewalls and the bottom of the deep trench 112. The seed layer 121 is made of amorphous silicon formed by LPCVD. A photoresist layer (not shown) fills the deep trench 112. Then, the upper portion of the photoresist layer in the deep trench 112 is removed; the portion of the photoresist layer beneath the collar oxide layer 114 remains. The remaining photoresist layer is identified as photoresist layer 122 hereafter.

Referring to FIG. 1H, the seed layer 121 on the pad layer 107 and above the top surface of the photoresist layer 122 in the deep trench 112 is removed. The remaining seed layer 121 is identified as residual seed layer 121′ hereafter. Then, the photoresist layer 122 is removed.

Referring to FIG. 1I, a hemispherical silicon grain layer 126 is formed on the surface of the residual seeding layer 121′, which is on the sidewalls and the bottom of the deep trench 112. The reaction conditions are as follows: the reaction temperature is 500 to 600° C.; The pressure is 1×10⁻⁸ to 1×10⁻⁶ Pa; The main reactant is silane. The hemispherical silicon grain layer 126 is formed by Low Pressure CVD (referred to as LPCVD hereafter).

Referring to FIG. 1J, the phosphorus ions are driven into the hemispherical silicon grain layer 126 by implantation or drive-in process. Then, a bottom electrode 130 is formed by another drive-in process. The arsenic ions in the residual doped insulating 120′ are driven into the substrate 100 until the junction depth is about 800 angstroms.

Referring to FIG. 1K, a capacitor dielectric layer 140 is formed on the surface of the bottom electrode 130. Then, a conductive layer 145 (not shown) is deposited to fill the deep trench 112. The conductive layer 145 is made of polycrystalline silicon in-situ doped with arsenic ions or phosphorus ions. A portion of the conductive layer 145 in the deep trench 112 is removed. The portion of the conductive layer 145 surrounded by the capacitor dielectric layer 140 is remained to form the top electrode 142 to complete the manufacturing of the trench capacitor of a memory cell.

Utilizing the hemispherical silicon grains to enlarge the surface area of the bottom electrode and the capacitance of the deep trench capacitor has been used in the conventional process for manufacturing the trench capacitor. According to the conventional process, hemispherical silicon grains are formed all over the sidewalls of the deep trench. Since there are capacitor and transistor (that is vertical transistor) in a deep trench, the hemispherical silicon grains have to be formed selectively on the lower portion of the sidewalls of a deep trench. Many complicated steps are used to remove the hemispherical silicon grains formed on the upper portion of sidewalls of a deep trench in conventional processes. The complicated steps in manufacturing semiconductors means longer cycle time and higher costs. Of course, shorter cycle time and lower cost are most manufacturers'goals. In this invention, fewer steps to accomplish the same are set forth. After forming a collar oxide layer at the upper portion of the sidewalls of a deep trench, ion implantation is used to form the seeding layer, which is the amorphous silicon, on the specified area of the lower portion of the sidewalls of a deep trench. The incident angle of the ion implantation is controlled, so as to define the area to form the seeding layer. When the incident angle of the ion implantation changes, the area to form the seeding layer also changes. Since the collar oxide layer is not affected by the ion implantation process, only the exposed substrate in a deep trench forms the seeding layer. The seeding layer forms the hemispherical silicon grains layer, and then forms the bottom electrode of the trench capacitor.

### SUMMARY OF THE INVENTION

Accordingly, an object of the present invention is to provide a method for fabricating a semiconductor memory device having a trench capacitor that can provide larger capacitance.

Accordingly, an object of the present invention is to provide a method for fabricating a semiconductor memory device with fewer process steps.

In order to achieve the above object, a method of fabricating a trench capacitor according to an embodiment of the present invention comprises first providing a semiconductor substrate. A pad layer is formed on a surface of the substrate. A deep trench is formed in the substrate. A first insulating layer is formed on the exposed surface of the substrate in the deep trench. A second insulating layer is formed to cover the pad layer and extends into the trench to cover the surface of the first insulating layer. A photoresist layer is formed to fill the deep trench. A portion of the photoresist layer is removed. The second insulating layer and the first insulating layer above the top surface of the residual photoresist layer are removed in sequence. The residual photoresist layer is removed. A collar oxide layer on the surface of the upper portion of the deep trench is formed, which is above the top surface of the residual first insulating layer and the residual second insulating layer. The residual first insulating layer and the residual second insulating layer are removed. A seeding layer is formed on the lower portion of the deep trench, which is beneath the collar oxide layer. A hemispherical silicon grain layer is formed on the seeding layer. The predetermined ions implant into the hemispherical silicon grain layer. A bottom electrode is formed by driving the predetermined ions of the hemispherical silicon grain layer into the substrate. A capacitor dielectric layer is formed on the bottom electrode. A top electrode on the capacitor dielectric layer is formed to complete the fabrication of the trench capacitor of a memory cell.

### BRIEF DESCRIPTION OF THE DRAWINGS

The accompanying drawings forms a material part of this description, in which:

FIGS. 1A through 1K show schematic cross-sectional views is of a partially fabricated integrated circuit structure at successive stages in forming a trench capacitor of a DRAM cell of the prior art; and

FIGS. 2A through 2H show schematic cross-sectional views of a partially fabricated integrated circuit structure at successive stages in forming a trench capacitor of a DRAM cell according to an embodiment of the present invention.

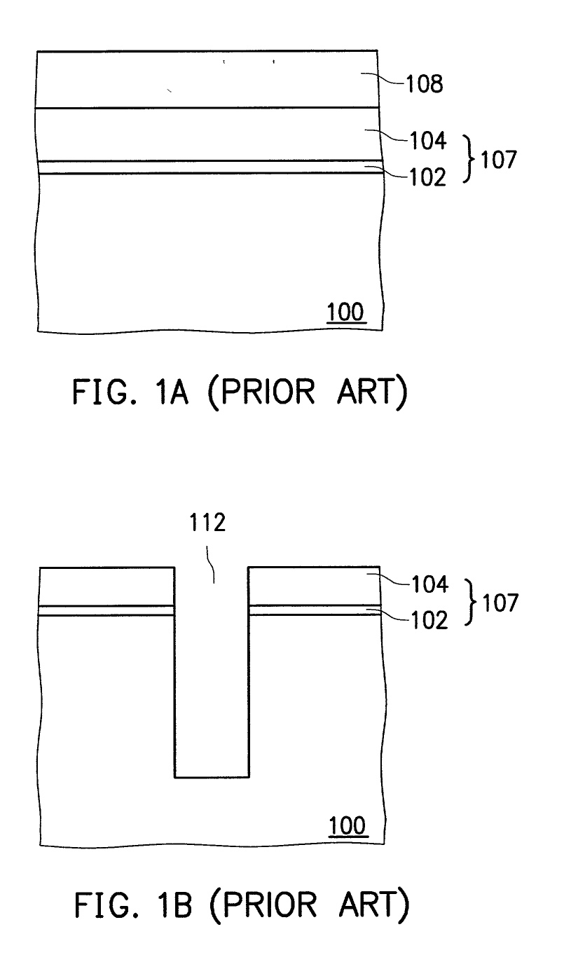

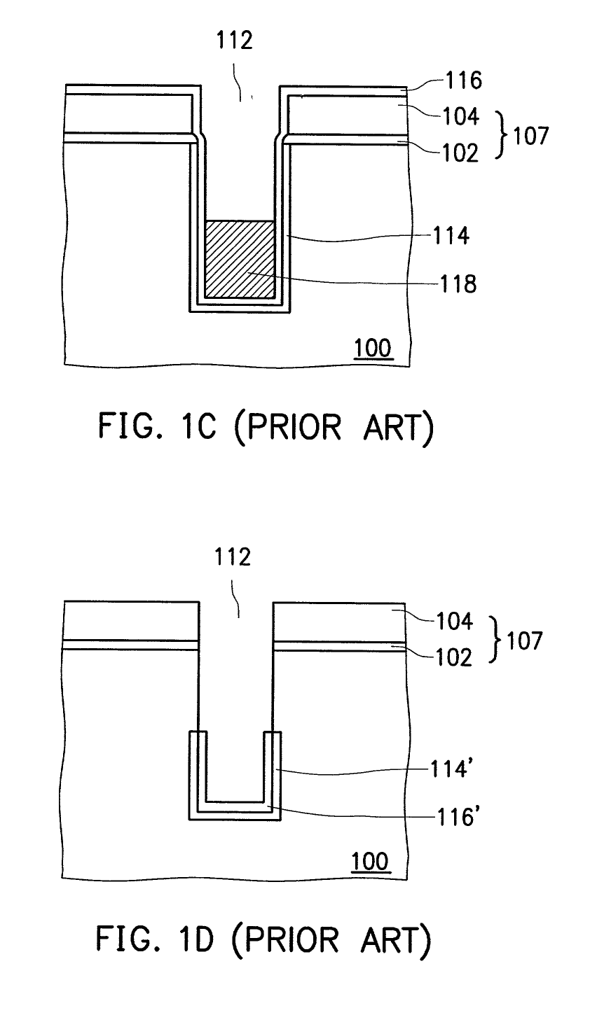

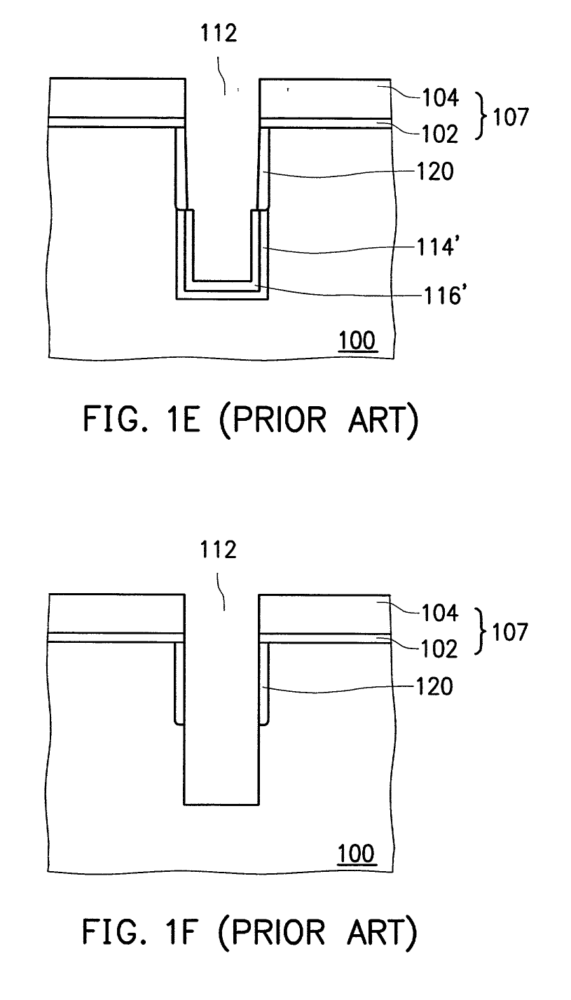

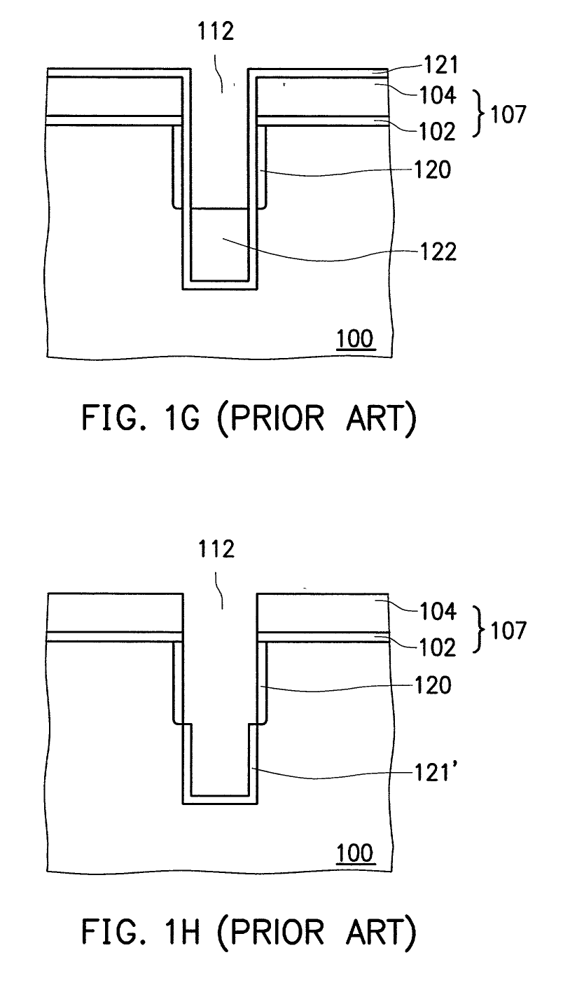

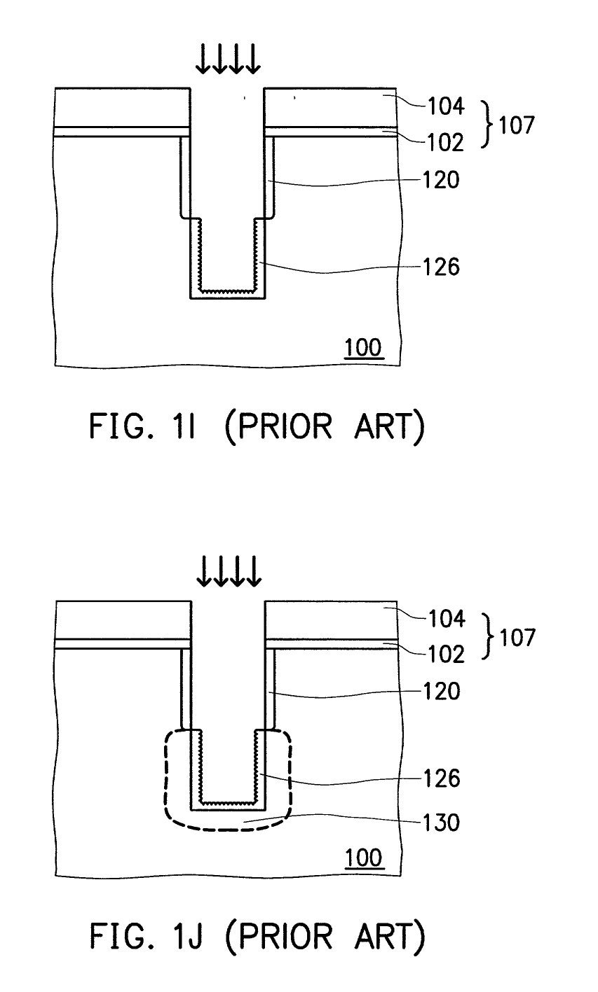

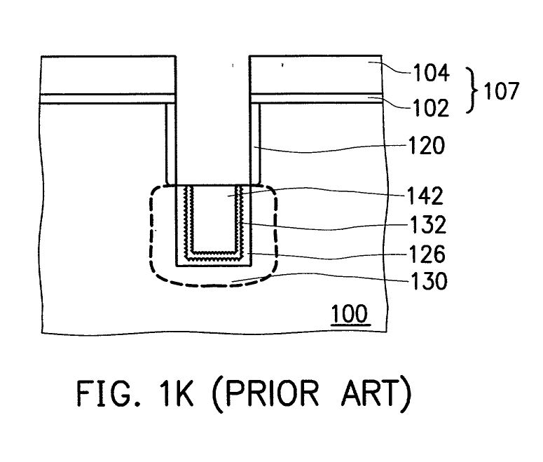

### DETAILED DESCRIPTION OF THE PREFERRED EMBODIMENT

The invention disclosed herein is directed to a method of fabricating the trench capacitor of DRAMs. In the following description, numerous details are set forth in order to provide a thorough understanding of the present invention. It will be appreciated by ones skilled in the art that variations of these specific details are possible while still achieving the results of the present invention. Well-known processing steps are not described in detail in order to avoid unnecessarily obscuring the present invention.

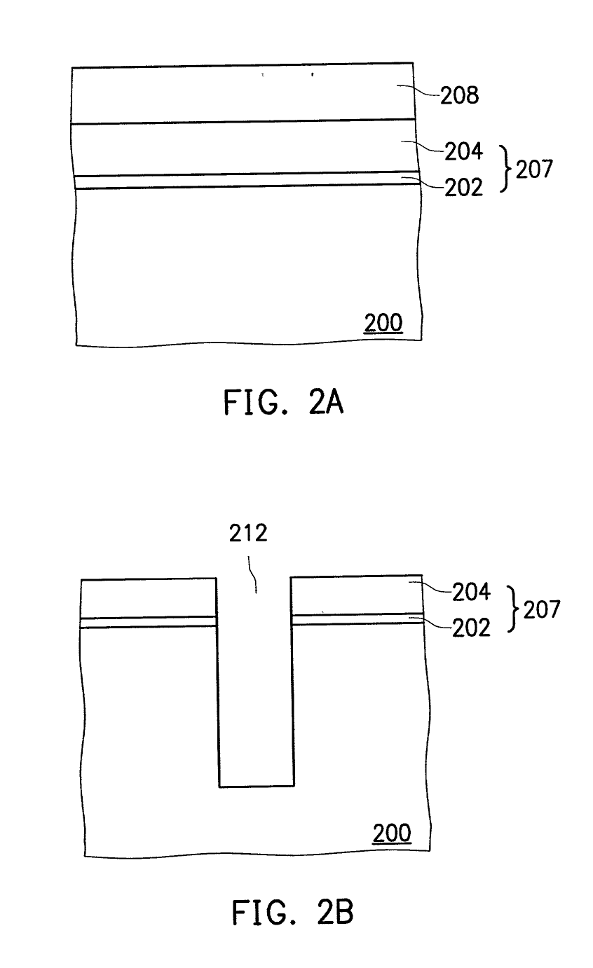

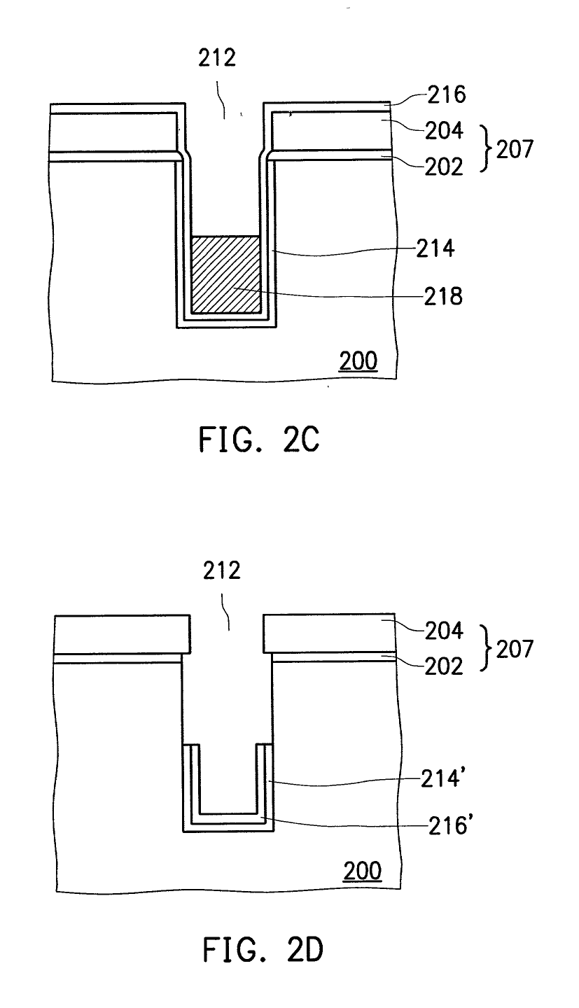

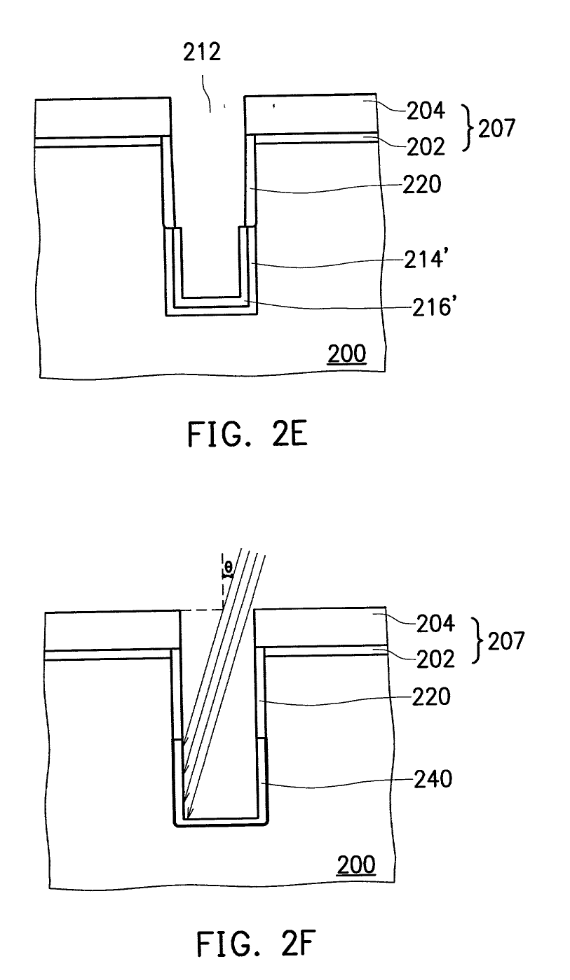

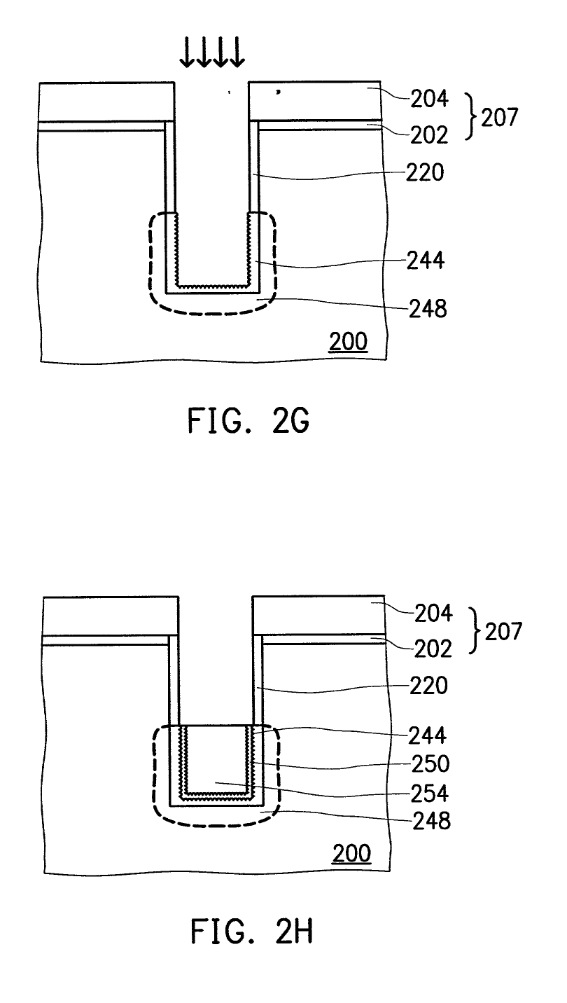

Referring now to FIG. 2A, a semiconductor substrate 200 is provided. The semiconductor substrate 200 is composed of silicon or germanium. The substrate 200 can be made by Epitaxial silicon or silicon on insulator (SOI). For simplicity, a P-type semiconductor silicon substrate 200 is taken as an example in this invention. An oxidation is used to form a pad oxide layer 202 on the surface of the substrate 200. The thickness of the pad oxide layer 202 is about 50 to 600 angstroms. A pad nitride layer 204, which has a thickness of about 1600 to 3000 angstroms, is then formed over the pad oxide 202 by CVD. The pad oxide 202 and the pad nitride 206 constitute the pad layer 207. A first masking layer 208 is formed over the pad layer 207. The masking layer 208, which has a thickness of about 5000 to 20000 angstroms, is made of boron silicate glass (BSG). The masking layer 208 can be formed by CVD, APCVD, SAPCVD, LPCVD, PECVD or HDPCVD and with in-situ doped boron ions in silicate glass. Thereafter, the masking layer 208 is planarized by thermal reflow, etchback or chemical mechanical polishing (CMP) techniques.

Referring to FIG. 2B, the masking layer 208 is defined by photolithography and etching. Then, the pad layer 207 and the substrate 200 are defined to form a deep trench 212 on the substrate 200 by using the masking layer 208 as a mask. The deep trench 212 has a depth of 6 to 7 micron meters. After the formation of the deep trench 212, the masking layer 208 is removed by isotropic etching, in which the pad layer 207 is used as the etching stop layer.

Referring to FIG. 2C, a first insulating layer 214 is formed on the sidewalls of the deep trench 212, which is the exposed surface of the substrate 200. The first insulating layer 214, which has a thickness of about 20 to 200 angstroms, is usually made of oxide silicon formed by oxidation or APCVD. Then, a second insulating layer 216, which has a thickness of 20 to 1500 angstroms, is formed to cover the pad layer 207 and extends into the trench 212 to cover the surface of the first insulating layer 214. The second insulating layer can be made of nitride silicon formed CVD. A photoresist layer (not shown) fills the deep trench 212. Then, the upper portion of the photoresist layer, which is 1500 to 20000 angstroms under the surface of the substrate 200, is removed. Hereafter, the remaining photoresist layer is presented as the photoresist layer 218.

Referring to FIG. 2D, portions of the second insulating layer 216 and the first insulating layer 214, which are above the top surface of the photoresist layer 218, can be removed in sequence by anisotropic etching. Then, the photoresist layer 218 is removed. Hereafter, the remaining first insulating layer 214 and the remaining second insulating layer 216 are referred to as the residual first insulating layer 214′ and the residual second insulating layer 216′.

Referring to FIG. 2E, a collar oxide layer 220 is formed on the surface of the upper portion of the deep trench 212, which is above the top surface of the residual first insulating layer 214′ and the residual second insulating layer 216′. The collar oxide layer 220 can be made of silicon oxide formed by oxidation and has a thickness of 200 to 500 angstroms.

Referring to FIG. 2F, the residual first insulating layer 214′ and the residual second insulating layer 216′ are removed by isotropic etching. A minimal portion of the collar oxide layer 220 is removed during etching, with no effect on the following processes. A seeding layer 240 is formed on the surface of the lower portion of the deep trench 212, which is beneath the collar oxide layer 220. The seeding layer 240 is made of amorphous silicon. The seeding layer 240 has a thickness of about 100 to 200 angstroms. Predetermined ions are implanted into the sidewalls and the bottom of the deep trench 212 at a specified angle. The predetermined ions can be the inert gases ions, such as argon or xenon. The specified angle of the implantation is identified as θ (from vertical). According to the equation: Tanθ=(the width of the deep trench 212/the depth of the deep trench 212), angle θ is determined by the width and the depth of the deep trench 212. Angle θ has an approximate range between 0 to 30 degrees. In order to conformally implant the inert gas ions into the sidewalls and the bottom of the deep trench 212, the wafer has to rotate constantly. Thus, the exposed surface of the deep trench 212 becomes the seeding layer 240.

Referring to FIG. 2G, a hemispherical silicon grain layer 244 is formed on the seeding layer 240 by LPCVD. The reaction conditions are as follows: the reaction temperature is about 500 to 600° C.; the reaction pressure is about 1×10⁻⁸ to 1×10⁻⁶ Pa; the main reactant can be Silane; the reaction time is about 5 to 20 minutes. Then, some ions such as phosphorus or arsenic are implanted into the hemispherical silicon grain layer 244 by implantation or drive-in techniques. The dose of the implantation is about 3-7E19/cm³. Afterwards, the ions are driven into the substrate 200 until the junction depth is about 800 to 1200 angstroms by drive-in to form the bottom electrode 248.

Referring to FIG. 2H, a capacitor dielectric layer 250 is formed on the bottom electrode 240. This layer is typically composed of layers of Si₃N₄ /SiO₂ (NO), or layers of SiO₂/Si₃N₄/SiO₂ (ONO) or only a layer of Tantalum oxide. A conductive layer (not shown), which is made of polycrystalline silicon in-situ doped with arsenic ions or phosphorus ions by LPCVD, fills up the deep trench 212. The conductive layer has a thickness of about 2500 to 3500 angstroms. Then, etch-back is performed to remove a portion of the conductive layer above the top surface of the bottom electrode 240. Then, the top electrode 254 is formed. The fabrication of a trench capacitor of a memory cell is then completed.

It is to be understood that although the present invention has been described with reference to a particular preferred embodiment, it should be appreciated that numerous modifications, variations and adaptations may be made without departing from the scope of the invention as defined in the claims.

It is to be understood that although the present invention has been described with reference to a particular preferred embodiment, it should be appreciated that numerous modifications, variations and adaptations may be made without departing from the scope of the invention as defined in the claims.

What is claimed is:

1. A method of fabricating the trench capacitor of a memory cell, comprising:
providing a semiconductor substrate;
forming a pad layer on a surface of said substrate;
forming a deep trench in said substrate;
forming a first insulating layer on the exposed surface of said substrate in said deep trench;
forming a second insulating layer to cover said pad layer and extends into said trench to cover the surface of said first insulating layer;
forming a photoresist layer to fill said deep trench;
removing a portion of said photoresist layer;
removing said second insulating layer and said first insulating layer above the top surface of said residual photoresist layer in sequence;
removing said residual photoresist layer;
forming a collar oxide layer on the surface of the upper portion of said deep trench, which is above the top surface of said residual first insulating layer and said residual second insulating layer;
removing said residual first insulating layer and said residual second insulating layer;
forming a seeding layer on the lower portion of said deep trench, which is beneath said collar oxide layer;
forming a hemispherical silicon grain layer on said seeding layer;
implanting predetermined ions into said hemispherical silicon grain layer;
forming a bottom electrode by driving said predetermined ions of said hemispherical silicon grain layer into said substrate;
forming a capacitor dielectric layer on said bottom electrode; and
forming a top electrode on said capacitor dielectric layer.

2. The method of claim 1, wherein the semiconductor substrate is made of silicon.

3. The method of claim 1, wherein the pad layer is composed of a pad nitride layer and a pad oxide layer.

4. The method of claim 1, wherein said first insulating layer is made of oxide silicon formed by oxidation.

5. The method of claim 1, wherein said first insulating layer is made of oxide silicon formed by APCVD.

6. The method of claim 1, wherein said first insulating layer has a thickness of about 20 to 200 angstroms.

7. The method of claim 1, wherein said second insulating layer is made of nitride silicon.

8. The method of claim 1, wherein the second insulating layer has a thickness of about 20 to 1500 angstroms.

9. The method of claim 1, wherein a portion of said photoresist layer is removed, whereas the portion is about 5000 to 15000 angstroms under the surface of said substrate remains.

10. The method of claim 1, wherein said collar oxide layer is made of silicon oxide formed by oxidation.

11. The method of claim 1, wherein said collar oxide layer has a thickness of about 200 to 500 angstroms.

12. The method of claim 1, wherein said seeding layer is made of amorphous silicon.

13. The method of claim 1, wherein said seeding layer has a thickness of about 100 to 200 angstroms.

14. A method of claim 1, wherein said seeding layer is formed by implanting predetermined ions into the sidewalls and the bottom of said deep trench at a specified angle.

15. The method of claim 14, wherein said predetermined ions are inert gases ions.

16. The method of claim 14, wherein said specified angle has an approximate range between 0 to 30 degrees from vertical.
